(19) United States
(12) Patent Application Publication
(10) Pub. No.: US 2005/0079448 A1
(43) Pub. Date: Apr. 14, 2005

(54) Method for forming resist pattern

(75) Inventors: Katsuyuki Nakada, Tokyo (JP); Mitsuru Takai, Tokyo (JP); Kazuhiro Hattori, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK CORPORATION, Tokyo (JP)

(21) Appl. No.: 10/925,038

(22) Filed: Aug. 25, 2004

(30) Foreign Application Priority Data
Aug. 27, 2003 (JP) 2003-303170

(51) Int. Cl. G03F 7/00

(52) U.S. Cl. 430/296; 430/322; 430/323

(57) ABSTRACT

A material having an amorphous structure is used as a ground material on which a resist layer is applied. After the resist layer is irradiated with an exposure electron beam to form latent images, the latent images are developed so that a predetermined line-and-space pattern is formed in the resist layer.

### BACKGROUND OF THE INVENTION

The present invention relates to a method for forming a resist pattern by irradiating a resist layer with an exposure electron beam and mainly relates to a method for producing a magnetic recording medium or a stamp. The invention can be applied to semiconductor micro-machining process or the like.

Remarkable improvement in a real recording density has been heretofore attained by improvement in a magnetic recording medium such as a hard disk concerning reduction in size of magnetic particles constituting a recording layer, change of material, micro-machining of a head, and so on. There is expectation that greater improvement in a real recording density will be brought in the future. A problem of side fringe, crosstalk, etc. caused by the limit of processing of a head and the spread of magnetic field, however, has become manifest. Improvement in a real recording density based on improvement methods according to the background art has reached the limit. Therefore, a discrete track type magnetic recording medium having a continuous recording layer partitioned into a large number of split recording elements has been proposed as a candidate for a magnetic recording medium in which greater improvement in a real recording density can be actualized (e.g. see JP-A-09-97419/(1997)).

In the discrete track type magnetic recording medium, rapid improvement in recording density has been attained and reduction in processed pattern size has advanced. For production of the discrete track type magnetic recording medium, there has been proposed a nano-imprinting method for forming a pattern in a resist layer by pressing a stamp having a predetermined line-and-space pattern (concave-convex pattern) against the resist layer. Reduction in size of the line-and-space pattern of the stamp or reduction in size of a line-and-space pattern of a stamp master matrix used for producing the stamp has advanced with the advance of reduction in processed pattern size.

To produce such a micro-pattern accurately, there is used a technique using an exposure electron beam for drawing a pattern in the resist layer. Because the wavelength of the electron beam is shorter than that of light and the diffraction phenomenon of the electron beam can be ignored, a micro-pattern can be drawn in the resist layer accurately. For example, a master matrix used for producing a stamp is produced by use of an exposure electron beam as follows. A resist layer applied on a support substrate is irradiated with an electron beam in accordance with a desired pattern. Then, development is performed to form a predetermined line-and-space pattern (concave-convex resist pattern). Thus, a master matrix used for producing a stamp is produced. When, for example, an electrically conductive film of Ni is formed on the master matrix and an electroplating process is performed with the electrically conductive film used as an electrode, a stamp can be produced. On this occasion, it is necessary to use an electrically conductive material as the material of the support substrate to prevent charging-up due to the electron beam. Although a Si substrate or the like is used as the support substrate in the background art (e.g. see JP-A-2003-6944), the substrate used has a crystalline structure.

In the background-art method, there is however a problem that fluctuation of line edge portions of the formed resist pattern (hereinafter referred to as “line edge roughness”) becomes large as shown in FIG. 1. The influence of line edge roughness on the pattern size cannot be by passed with the advance of reduction in processed pattern size of the magnetic recording medium or the stamp. A technique for forming a resist pattern as small in line edge roughness as possible is required.

### SUMMARY OF THE INVENTION

The invention is developed in consideration of the fore going problem and a chief object of the invention is to provide a method for forming a resist pattern small in line edge roughness.

In the invention, a material having an amorphous structure is used as a ground material on which a resist layer is applied, so that a resist pattern with small line edge roughness is formed.

The reason why use of a material having an amorphous structure as a ground material on which a resist layer is applied makes it possible to reduce line edge roughness is not necessarily obvious but may be conceived chiefly as follows. It is conceived that scattering (back-scattering) of the incident electron beam generated in the interface between the resist layer and the ground material is a cause of occurrence of line edge roughness in the resist pattern.

When, for example, the ground material has a crystalline structure like a single crystal Si substrate, back-scattering intensity becomes uneven because back-scattering is intensified in a specific direction according to the crystalline structure. It is conceived that the line edge roughness of the resist pattern becomes large because the resist layer reacts with the scattered beam unevenly. It is conceived that when a material having an amorphous structure is used as the ground material, unevenness in back-scattering intensity is suppressed so that the line edge roughness becomes small.

That is, solution of the problem is attained by the following configuration of the invention.
(1) A method of forming a resist pattern, having the steps of: forming a resist layer on a support substrate having an amorphous structure; forming latent images in the resist layer by irradiating the resist layer with an exposure electron beam; and developing the latent images to thereby form a predetermined line-and-space pattern in the resist layer.
(2) A method of forming a resist pattern, having the steps of: forming a ground material having an amorphous structure and a resist layer successively on a support substrate; forming latent images in the resist layer by irradiating the resist layer with an exposure electron beam; and developing the latent images to thereby form a predetermined line-and-space pattern in the resist layer.
(3) Further, according to the present invention, a method of producing a master matrix used for producing a stamp, having the step of forming a resist pattern by a method of forming a resist pattern described above.
(4) Moreover, according to the present invention, a method of forming a mask, including the steps of: forming a mask layer having an amorphous structure on a subject to be machined; forming a resist layer on the mask layer; forming latent images in said resist layer by irradiating said resist layer with an exposure electron beam; developing said latent images to form a resist pattern; and transferring said resist pattern to said mask to thereby form a predetermined line-and-space pattern in said mask.

In the resist pattern forming method according to the invention, it is conceived that because the ground material under the resist layer in which a predetermined line-and-space pattern is formed by exposure electron beam irradiation has an amorphous structure, unevenness in back-scattering intensity of the incident electron beam generated in the interface between the resist layer and the ground material is suppressed so that a fine resist pattern with small line edge roughness can be formed.

In the method of producing a master matrix used for producing a stamp, having the step of forming a resist pattern by the resist pattern forming method, a master matrix which is used for producing a stamp and in which a fine line-and-space pattern with small line edge roughness is formed can be produced.

In the mask pattern forming method according to the invention, because the mask has an amorphous structure, the resist pattern formed on the mask can be provided as a fine resist pattern with small line edge roughness. When a mask pattern is formed by transferring the resist pattern, the mask pattern can be provided as a fine mask pattern with small line edge roughness. When the mask pattern is used for processing a subject as a layer under the mask pattern, the subject can be processed into a pattern with small line edge roughness.

### BRIEF DESCRIPTION OF THE DRAWINGS

FIG. 1 is a typical view for explaining line edge roughness of a resist pattern.

FIG. 2 is a side sectional view typically showing a state in which a resist layer 11 is formed on a substrate 10 according to a first embodiment of the invention.

FIG. 3 is a side sectional view typically showing a state in which latent images Ri1 are formed in the resist layer 11 by electron beam EB irradiation.

FIG. 4 is a side sectional view typically showing a state in which development of the resist layer 11 (formation of a resist pattern Rp1) is completed (a state in which a stamp master matrix 12 is completed).

FIG. 5 is a side sectional view typically showing a state in which an electrically conductive film 13 is formed so that the resist pattern Rp1 is covered with the electrically conductive film 13.

FIG. 6 is a side sectional view typically showing a state in which a metal film 14 is formed on the electrically conductive film 13.

FIG. 7 is a side sectional view typically showing a state in which a laminate (stamp 15) of the electrically conductive film 13 and the metal film 14 is separated.

FIG. 8 is a side sectional view typically showing the stamp 15 produced by the production method according to the first embodiment of the invention.

FIG. 9 is a side sectional view typically showing a stamp master matrix 12′ according to a modification of the first embodiment of the invention.

FIG. 10 is a side sectional view typically showing the configuration of a starting body of a sample according to a second embodiment of the invention.

FIG. 11 is a side sectional view typically showing the structure of a finished product of the sample obtained by processing the starting body.

FIG. 12 is a side sectional view typically showing a state in which a second mask layer 24 is formed on the starting body.

FIG. 13 is a side sectional view typically showing a state in which a resist layer 25 is formed on the second mask layer 24.

FIG. 14 is a side sectional view typically showing a state in which latent images Ri2 are formed in the resist layer 25 by electron beam EB irradiation.

FIG. 15 is a side sectional view typically showing a state in which development of the resist layer 25 (formation of a resist pattern Rp2) is completed.

FIG. 16 is a side sectional view typically showing the shape of the sample after removal of the second mask layer from the bottom of grooves.

FIG. 17 is a side sectional view typically showing the shape of the sample after removal of the first mask layer from the bottom of the grooves.

FIG. 18 is a side sectional view typically showing the shape of the sample after partitioning of the magnetic thin-film layer.

FIG. 19 is a typical view for explaining a line edge roughness measuring method concerning Examples and Comparative Examples.

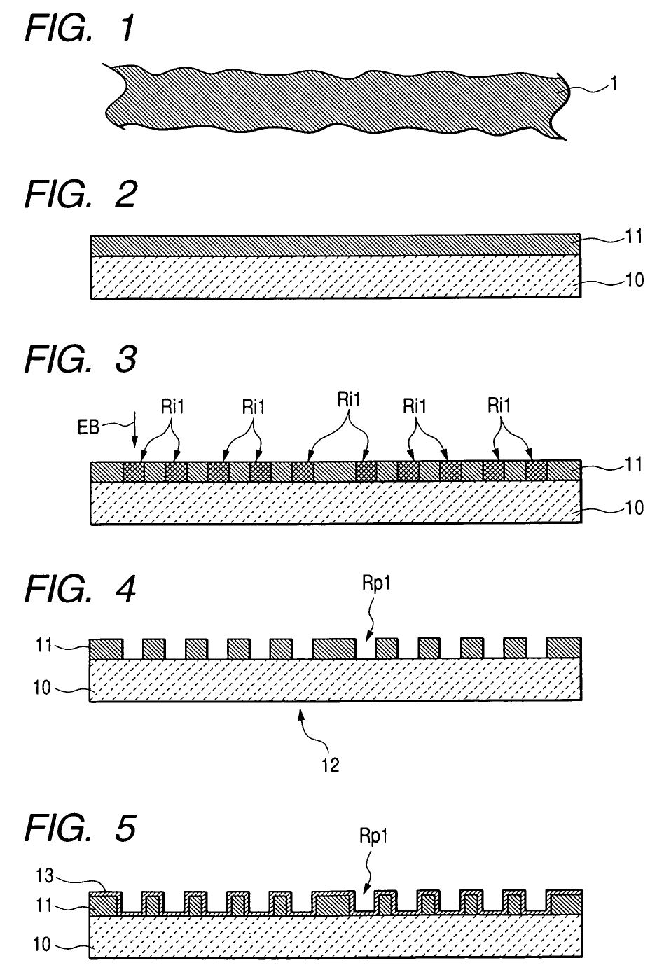

### DETAILED DESCRIPTION OF THE PREFERRED EMBODIMENTS

Preferred embodiments of the invention will be described below in detail with reference to the drawings.

(First Embodiment)

First, a first preferred embodiment of the invention (a method for producing a master matrix used for producing a stamp) will be described in detail with reference to the drawings.

First, as shown in FIG. 2, a positive-type electron beam resist (e.g. trade name: ZEP520A (made by Zeon Corp.)) is applied on a substrate 10 having an electrically conductive amorphous structure shaped like a flat plate, by a spin coating method to thereby form a resist layer 11 about 130 nm thick. In this case, for example, an amorphous Si substrate shaped like a flat plate having a surface polished to be flattened is used as the substrate 10.

Then, a baking process is executed at 180° C. for about 5 minutes to thereby harden the resist layer 11. Then, as shown in FIG. 3, the resist layer 11 on the substrate 10 in this state is irradiated with a patterning electron beam EB by an electron beam drawing apparatus so that the electron beam EB is applied on portions where concave portions of a stamp master matrix will be formed. For example, as a result, latent images Ri1, Ri1 . . . shaped like concentric circles each having a width of about 76 nm and arranged at intervals of a pitch of about 150 nm are formed in the resist layer 11.

Because the ground material under the resist layer has an amorphous structure, unevenness in back-scattering intensity of the incident electron beam generated in the interface between the resist layer and the ground material is suppressed so that latent images Ri1 with small line edge roughness are obtained.

Then, the resist layer 11 in this state is developed by a developing apparatus. As a result, as shown in FIG. 4, the portions of the latent images Ri1 are removed to partially reveal the hidden surface of the substrate 10. In this case, for example, trade name: ZED-N50 (made by Zeon Corp.) is used as a developing solution. The substrate 10 is immersed in the developing solution for 3 minutes in the condition that the temperature of the developing solution is set at 26° C. As a result, a resist pattern Rp1 is formed on the substrate 10. Then, the substrate 10 in this state is immersed in a rinsing solution (e.g. trade name: ZMD-D (made by Zeon Corp.)) at 23° C. (room temperature). Then, nitrogen gas is blown on the substrate 10 by a drying apparatus to thereby dry the resist pattern Rp1 (resist layer 11). Thus, the resist pattern with small line edge roughness is formed. As a result, a stamp master matrix 12 as shown in FIG. 4 is completed.

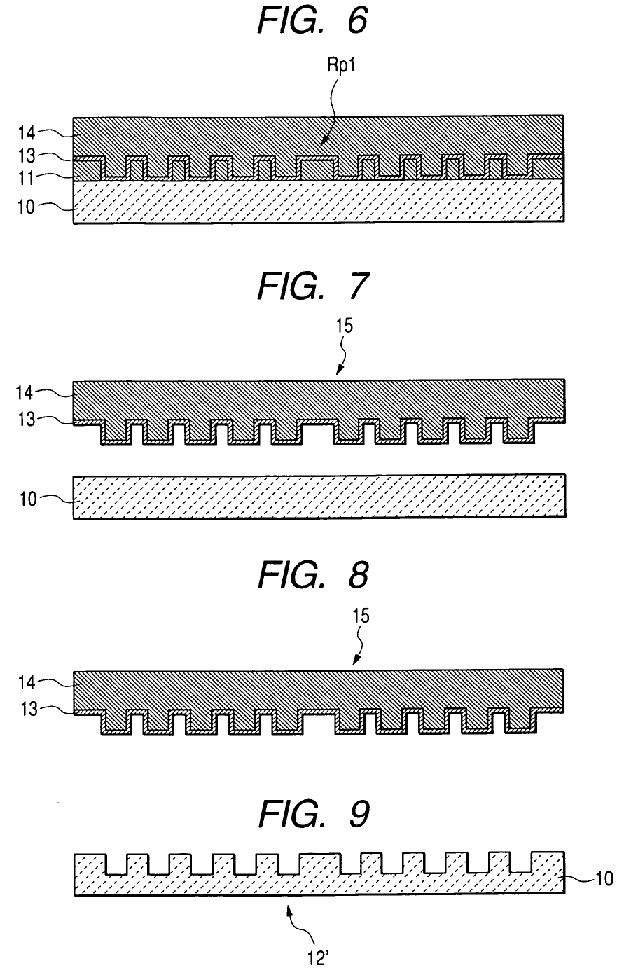

A method for producing a stamp by using the stamp master matrix 12 will be described with reference to FIGS. 5 to 8. As shown in FIG. 5, Ni vapor is deposited on the resist pattern Rp1 to form an electrically conductive film 13 about 30 nm thick. Then, as shown in FIG. 6, an electroplating process with the electrically conductive film 13 used as an electrode is performed by an electro forming apparatus so that a metal film (electrolytic nickel film) 14 about 120 μm thick is formed on the electrically conductive film 13. Then, the laminate of the substrate 10, the resist layer 11, the electrically conductive film 13 and the metal film 14 is immersed in a resist parting solution to dissolve the resist layer 11. As a result, as shown in FIG. 7, the laminate of the electrically conductive film 13 and the metal film 14 is separated from the substrate 10. On this occasion, an exclusive parting apparatus may be used for the separation. In this manner, a stamp 15 as shown in FIG. 8 is completed.

As described above, in accordance with the method for forming a resist pattern and the method for producing a stamp master matrix, the ground material under the resist layer has an amorphous structure. For this reason, unevenness in back-scattering intensity of the incident electron beam generated in the interface between the resist layer and the ground material is suppressed so that a resist pattern with small line edge roughness is formed. In addition, it is possible to produce a stamp master matrix in which such a resist pattern (line-and-space pattern) with small line edge roughness is formed.

When the stamp master matrix produced in this manner is used for producing a stamp, the stamp can be produced as a stamp with small line edge roughness on the line-and-space pattern.

Incidentally, the invention is not limited to the embodiment and may be modified suitably. Although the first embodiment of the invention has been described on the case where a substrate having an electrically conductive amorphous structure shaped like a flat plate is used as the support substrate, the invention is not limited thereto. For example, a laminate of any substrate and a film having an electrically conductive amorphous structure and formed on the substrate may be used as the support substrate. In this case, the substrate on which the film having an amorphous structure is formed may have an amorphous structure or may have a crystalline structure if the film having an amorphous structure can be formed on the substrate. The substrate may be electrically conductive or nonconductive. A laminate of a substrate and a film having an electrically nonconductive amorphous structure may be used as the support substrate if the substrate on which the film is formed is electrically conductive. In this case, it is necessary to reduce the thickness of the formed film so that charging-up due to the electron beam can be prevented.

Although the first embodiment of the invention has been described on the case where amorphous Si is used as the substrate (ground material under the resist layer) having an amorphous structure, the invention is not limited thereto. For example, a material such as glass-like carbon having an amorphous structure may be used as the ground material. A laminate of an electrically conductive substrate and a film (of SiO₂ or the like) having an amorphous structure and formed on the substrate may be used as the ground material. In this case, because SiO₂ is electrically nonconductive, it is necessary to reduce the thickness of the formed film so that charging-up due to the electron beam can be prevented.

Although the first embodiment of the invention has been described on the case where a laminate of a substrate having an amorphous structure and a line-and-space pattern of the resist layer formed on the substrate is provided as a stamp master matrix, the invention may be applied to the case where a support substrate etched by a dry etching method or the like with a line-and-space pattern of the resist layer used as a mask (see FIG. 9) is provided as a stamp master matrix. Also in this case, the material of the support substrate to be dry-etched is not particularly limited if the ground material under the resist layer has an amorphous structure. Also in this case, because the line edge roughness of the resist pattern is small, a stamp master matrix with small line edge roughness on the line-and-space pattern can be produced. When the stamp master matrix produced in this manner is used for producing a stamp, the stamp can be produced as a stamp with small line edge roughness on the line-and-space pattern.

(Second Embodiment)

The invention can be also applied to a mask which is formed on a subject and used for processing the subject into a predetermined pattern and a method for forming a mask pattern to form a predetermined line-and-space pattern in the mask. Another preferred embodiment (second embodiment) will be described below in detail with reference to the drawings.

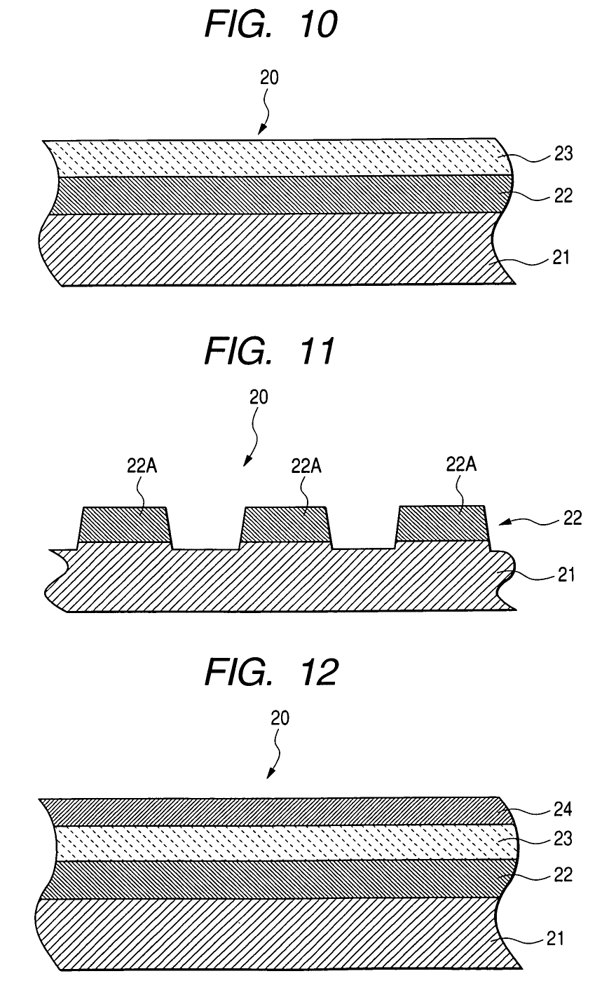

The second embodiment is configured so that processing such dry etching is applied to a starting body of a sample shown in FIG. 10 (an example of a subject to be processed according to the invention) to thereby process a magnetic thin-film layer (magnetic substance) into a predetermined line-and-space pattern shape as shown in FIG. 11. Because the configuration of an apparatus etc. used is the same as in the background art, the description of the apparatus etc. will be omitted suitably.

As shown in FIG. 10, the starting body of the sample 20 has a structure in which a magnetic thin-film layer 22 and a first mask layer 23 are formed successively on a glass substrate 21.

The magnetic thin-film layer 22 has a thickness of 5 nm to 30 nm and is made of a Co—Cr (cobalt-chrome) alloy. The first mask layer 23 has a thickness of 3 nm to 20 nm and is made of diamond-like carbon (a material having an amorphous structure containing carbon as a main component and exhibiting a hardness of about 200 kgf/mm² to 8000 kgf/mm² as a value measured with a Vickers hardness tester).

First, a second mask layer 24 having a thickness of 3 nm to 15 nm as shown in FIG. 12 is formed on the starting body of the sample 20 shown in FIG. 10, by a DC sputtering method with Si used as the material of the second mask layer 24 in the condition of Ar gas pressure of 0.3 Pa, applied power of DC 500 W and the substrate temperature of 25° C. When film formation is performed in this condition, a Si mask having an amorphous structure can be formed.

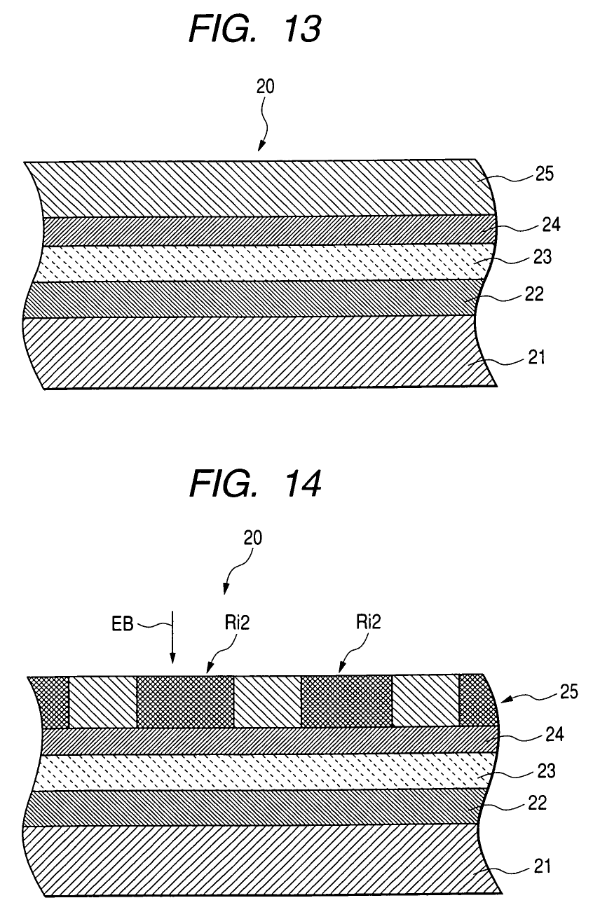

Then, a resist (e.g. positive-type electron beam resist ZEP520A made by Zeon Corp.) is applied on the second mask layer 24 by a spin coating method to thereby form a resist layer 25 having a thickness of 30 nm to 300 nm as shown in FIG. 13.

Then, a baking process is executed at 180° C. for about 5 minutes to thereby harden the resist layer 25. Then, the resist layer 25 on the sample 20 in this state is irradiated with a patterning electron beam EB by an electron beam drawing apparatus as shown in FIG. 14. For example, as a result, latent images Ri2, Ri2 . . . shaped like concentric circles each having a width of about 76 nm and arranged at intervals of a pitch of about 150 nm are formed in the resist layer 25.

Because the ground material under the resist layer has an amorphous structure, unevenness in back-scattering intensity of the incident electron beam generated in the interface between the resist layer and the ground material is suppressed so that latent images Ri2 with small line edge roughness are obtained.

Then, the resist layer 25 in this state is developed by a developing apparatus. As a result, as shown in FIG. 15, the portions of the latent images Ri2 are removed to thereby partially reveal the hidden surface of the second mask layer 24. On this occasion, for example, trade name: ZED-N50 (made by Zeon Corp.) is used as a developing solution. For example, the sample 20 is immersed in the developing solution for 3 minutes in the condition that the temperature of the developing solution is set at 26° C. As a result, a resist pattern Rp2 is formed on the second mask layer 24. Then, the sample 20 in this state is immersed in a rinsing solution (e.g. trade name: ZMD-D (made by Zeon Corp.)) at 23° C. (room temperature). Then, nitrogen gas is blown on the sample 20 by a drying apparatus to dry the resist pattern Rp2 (resist layer 25). In this manner, the resist pattern with small line edge roughness is formed.

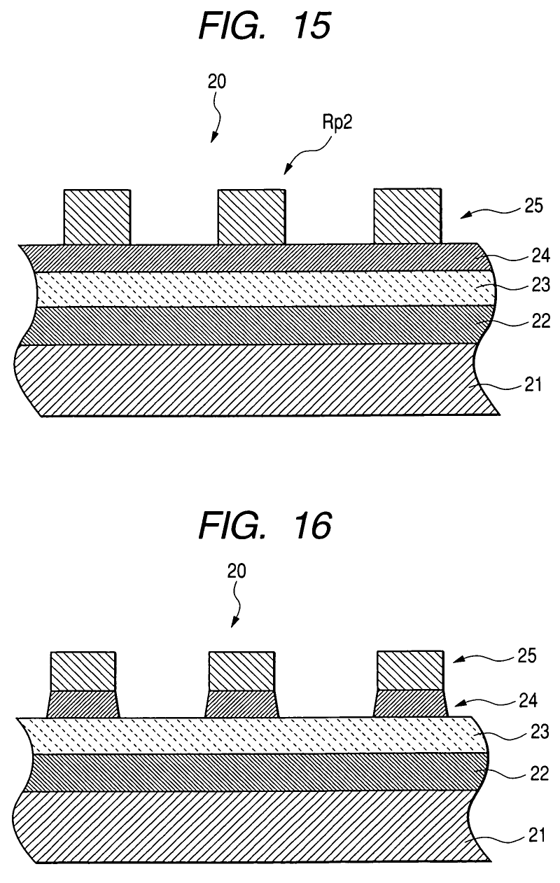

Then, reactive ion etching using CF₄ gas or SF₆ gas is performed so that portions of the second mask layer 24 revealed from the resist layer 25 are etched as shown in FIG. 16. The resist layer 25 is slightly removed from other regions than the grooves but remains still.

Then, reactive ion etching using oxygen gas or ozone gas is performed so that the resist layer 25 is removed from other regions than the grooves while the first mask layer 23 as the bottom of the grooves is removed as shown in FIG. 17. The second mask layer 24 is slightly removed from other regions than the grooves but a large part of the second mask layer 24 remains still.

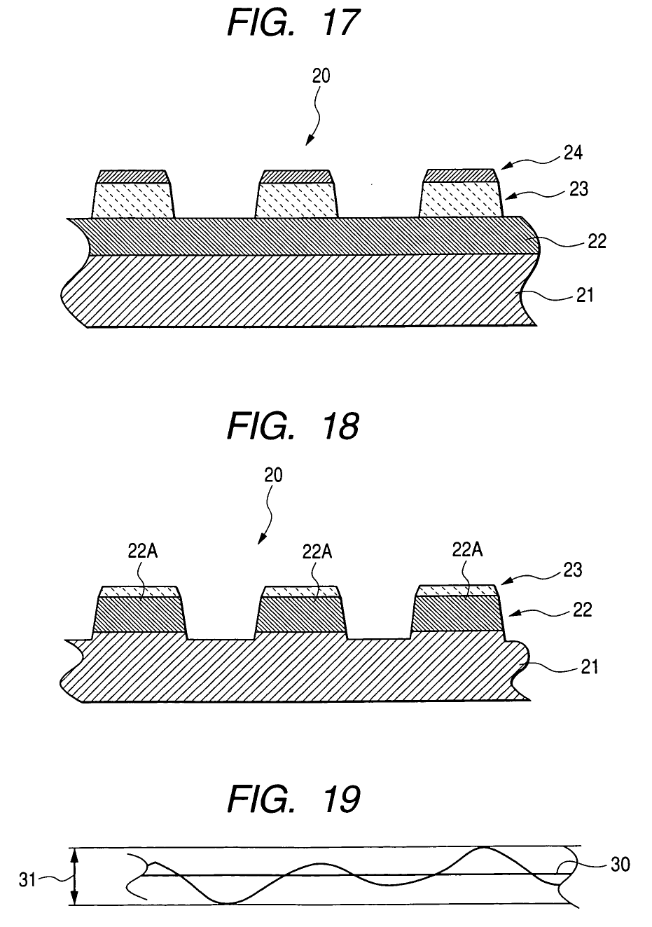

Then, ion beam etching using Ar gas is performed so that the magnetic thin-film layer 22 as the bottom of the grooves is removed as shown in FIG. 18. As a result, the magnetic thin-film layer 22 is partitioned into a large number of split recording elements 22A by groove portions formed between the split recording elements 22A. On this occasion, the second mask layer 24 in the other regions than the grooves is removed completely and a large part of the first mask layer 23 in the other regions than the grooves is removed but a small part of the first mask layer 23 can remain still on the split recording elements 22A.

Then, ashing using oxygen gas or ozone gas is performed so that the first mask layer 23 remaining on the split recording elements 22A is removed completely as shown in FIG. 11.

In this manner, processing of the sample 20 is completed.

As described above, because the mask used after a resist pattern formed by developing latent images formed by exposure electron beam irradiation is transferred to the mask has an amorphous structure, unevenness in back-scattering intensity of the incident electron beam generated in the interface between the resist layer and the ground mask is suppressed so that a resist pattern with small line edge roughness is formed. When the resist pattern with small line edge roughness is used for processing the mask layer, a mask pattern with small line edge roughness can be formed. When the mask pattern with small line edge roughness is used for processing the lower mask layer and the magnetic thin-film layer, these layers can be processed into a pattern with small line edge roughness.

Although this embodiment has been described on the case where the material of the second mask layer 24 used as the ground material under the resist layer is Si, the invention is not limited thereto. For example, any other material may be used as the ground material under the resist layer if a mask having an amorphous structure can be formed. In this case, the material is preferably selected in consideration of etching resistance or the like. The combination with another mask as a lower layer, the number of the laminated layers, the etching method, etc. may be controlled suitably so that a wide choice for materials can be obtained.

Although this embodiment has been described on the case where the sample 20 is a test sample formed in such a manner that the magnetic thin-film layer 22 is directly formed on the glass substrate 21, the invention may be applied to the case where, for example, an oriented layer, a soft magnetic layer, an undercoat layer or the like is formed between the glass substrate 21 and the magnetic thin-film layer 22. Although this embodiment has been described on the case where a Co—Cr alloy is used as the material of the magnetic thin-film layer 22, the invention is not limited thereto. For example, another alloy containing an iron-group element (Co, Fe, Ni) may be used as the material of the magnetic thin-film layer 22. It is a matter of course that the invention can be applied to microprocessing etc. of a recording medium such as a magnetic disk (e.g. a hard disk), an optomagnetic disk, a magnetic tape, etc., a magnetic head and a semiconductor.

### EXAMPLE 1

A resist pattern was formed on an amorphous Si substrate (substrate 10) according to the first embodiment. Thus, a resist pattern Rp1 having convex portions each having a width of about 74 nm and a height of about 130 nm was formed. The line edge roughness of the formed resist pattern was measured. The line edge roughness was measured as follows. As shown in FIG. 19, the width between two upper and lower points having line edge positions farthest from a reference line 30 parallel to the resist pattern was defined as line edge roughness 31. Five resist patterns were measured in such a manner that one side of each resist pattern was measured in the condition that a length of 800 μm which was the length of one side was set as a measurement range. Results of the measurement were as shown in Table 1.

### EXAMPLE 2

A resist pattern was formed on a second mask layer 24 according to the second embodiment. Thus, a resist pattern Rp2 having convex portions each having a width of about 74 nm and a height of about 130 nm was formed. The line edge roughness of the formed resist pattern was measured in the same manner as in Example 1. Results of the measurement were as shown in Table 1.

### EXAMPLE 3

A resist pattern was formed in the same manner as in Example 1 except that glass-like carbon (having an amorphous structure) was used as the substrate 10. Thus, a resist pattern Rp1 having convex portions each having a width of about 74 nm and a height of about 130 nm was formed. The line edge roughness of the formed resist pattern was measured in the same manner as in Example 1. Results of the measurement were as shown in Table 1.

### COMPARATIVE EXAMPLE 1

A resist pattern was formed in the same manner as in Example 1 except that a single crystal Si substrate was used as the substrate 10. Thus, a resist pattern Rp1 having convex portions each having a width of about 74 nm and a height of about 130 nm was formed. The line edge roughness of the formed resist pattern was measured in the same manner as in Example 1. Results of the measurement were as shown in Table 1.

### COMPARATIVE EXAMPLE 2

A resist pattern was formed in the same manner as in Example 3 except that a polycrystalline carbon substrate was used as the substrate 10. Thus, a resist pattern Rp1 having convex portions each having a width of about 74 nm and a height of about 130 nm was formed. The line edge roughness of the formed resist pattern was measured in the same manner as in Example 1. Results of the measurement were as shown in Table 1.

TABLE 1

| | Line Edge Roughness (nm) | | | | | |
|---|---|---|---|---|---|---|
| | Line | Line | Line | Line | Line | |
| | No. 1 | No. 2 | No. 3 | No. 4 | No. 5 | Average |
| Example 1 | 2.92 | 3.32 | 2.13 | 2.38 | 2.71 | 2.69 |
| Example 2 | 3.15 | 2.96 | 2.08 | 2.84 | 2.41 | 2.69 |
| Example 3 | 2.85 | 1.80 | 1.89 | 2.50 | 2.21 | 2.25 |
| Comparative | 3.65 | 1.96 | 3.54 | 4.65 | 3.15 | 3.39 |
| Example 1 | | | | | | |
| Comparative | 2.96 | 3.28 | 3.15 | 2.23 | 3.67 | 3.06 |
| Example 2 | | | | | | |

The measured results of the line edge roughness in Example 1 are substantially the same as those in Example 2. It is conceived that this is caused by the fact that Si having an amorphous structure is used as the ground material under the resist layer in both Example 1 and Example 2. In each of Examples 1 and 2, the resist pattern with small line edge roughness can be formed compared with that in Comparative Example 1. Also in Example 3, the resist pattern with small line edge roughness can be formed compared with that in Comparative Example 2. Even in the case where carbon is used as the ground material under the resist layer, it is confirmed that a resist pattern with small line edge roughness can be formed when a material having an amorphous structure is used as the ground material under the resist layer.

The invention can be applied to microprocessing of a magnetic recording medium, a stamp, a semiconductor, etc. and production of the magnetic recording medium, the stamp, the semiconductor, etc.

1. A method of forming a resist pattern, comprising the steps of:
forming a resist layer on a support substrate having an amorphous structure;
forming latent images in said resist layer by irradiating said resist layer with an exposure electron beam; and
developing said latent images to thereby form a predetermined line-and-space pattern in said resist layer.

2. A method of forming a resist pattern, comprising the steps of:
forming a ground material having an amorphous structure and a resist layer successively on a support substrate;
forming latent images in said resist layer by irradiating said resist layer with an exposure electron beam; and
developing said latent images to thereby form a predetermined line-and-space pattern in said resist layer.

3. A method of producing a master matrix used for producing a stamp, comprising the step of:
forming a resist pattern by a method of forming a resist pattern defined in claim 1.

4. A method of producing a master matrix used for producing a stamp, comprising the step of:
forming a resist pattern by a method of forming a resist pattern defined in claim 2.

5. A method of forming a mask, comprising the steps of:
forming a mask layer having an amorphous structure on a subject to be processed;
forming a resist layer on the mask layer;
forming latent images in said resist layer by irradiating said resist layer with an exposure electron beam;
developing said latent images to form a resist pattern; and
transferring said resist pattern to said mask to thereby form a predetermined line-and-space pattern in said mask.
